(19) United States
(12) Patent Application Publication
(10) Pub. No.: US 2025/0248285 A1
(43) Pub. Date: Jul. 31, 2025

(54) DISPLAY SUBSTRATE, METHOD OF MANUFACTURING THE SAME, AND DISPLAY DEVICE

(71) Applicants: Beijing BOE Technology Development Co., Ltd., Beijing (CN); BOE Technology Group Co., Ltd., Beijing (CN)

(72) Inventors: Tianhao Lu, Beijing (CN); Xiaohu Li, Beijing (CN); Qian Jin, Beijing (CN); Xu Liu, Beijing (CN); Hongli Wang, Beijing (CN); Tong Wu, Beijing (CN)

(21) Appl. No.: 18/702,428

(22) PCT Filed: Jul. 27, 2023
(86) PCT No.: PCT/CN2023/109457

§ 371 Date: Apr. 18, 2024

(51) Int. Cl. H10K 59/80; H10K 59/12; H10K 59/131; H10K 59/35

(52) U.S. Cl. CPC H10K 59/879; H10K 59/1201; H10K 59/131; H10K 59/35

(57) ABSTRACT

A display substrate is provided, including: a base substrate; pixel units arranged in an array in a display region, each pixel unit includes sub-pixels each including a sub-pixel opening defined by a pixel defining layer on the base substrate; sub-pixel lenses arranged in an array on a side of the pixel defining layer away from the base substrate. Each pixel unit includes at least two sub-pixels having a same color, an orthographic projection of the sub-pixel opening on the base substrate is parallelogram, and is located within that of the corresponding sub-pixel lens on the base substrate which is circle. Adjacent side edges of two adjacent sub-pixel openings are arranged parallel to each other and spaced apart by a first distance D1, and closest points between adjacent sub-pixel lenses are spaced apart by a second distance D2 less than the first distance D1.

### CROSS-REFERENCE TO RELATED APPLICATION(S)

This application is a Section 371 National Stage Application of International Application No. PCT/CN2023/109457, filed on Jul. 27, 2023, entitled “DISPLAY SUBSTRATE, METHOD OF MANUFACTURING THE SAME, AND DISPLAY DEVICE”, the whole disclosure of which is incorporated herein by reference in its entirety.

### TECHNICAL FIELD

The present disclosure relates to the field of display technology, and specifically to a display substrate, a method of manufacturing the same, and a display device.

### BACKGROUND

OLED display technology is getting mature, but still has problems. For example, OLED has a low pixel brightness, and a pixel opening rate is limited to a certain extent with an increasing demand for a pixel density on a mobile apparatus. In the related art, the pixel brightness may be improved by increasing a current, but a service life of the display apparatus may be significantly reduced. The brightness may also be improved by providing lenses on the OLED, but the pixel density of the display apparatus may be reduced on a basis of an original opening rate, and it is difficult to design a display device with high brightness and high opening rate.

The above information disclosed in this section is just for understanding of the background of technical concept of the present disclosure. Therefore, the above information may contain information that does not constitute the related art.

### SUMMARY

In an aspect, a display substrate having a display region is provided, the display substrate including: a base substrate; a plurality of pixel units arranged in an array in the display region, each pixel unit includes a plurality of sub-pixels, and the sub-pixels include sub-pixel openings defined by a pixel defining layer provided on the base substrate: a plurality of sub-pixel lenses arranged in an array on a side of the pixel defining layer away from the base substrate, the sub-pixel lenses have corresponding sub-pixel openings in the pixel defining layer on a side close to the base substrate, the plurality of sub-pixels of each pixel unit include at least two sub-pixels having a same color: an orthographic projection of the sub-pixel opening on the base substrate is a parallelogram, an orthographic projection of the sub-pixel lens on the base substrate is a circle, and the orthographic projection of the sub-pixel opening on the base substrate is located within the orthographic projection of the corresponding sub-pixel lens on the base substrate: adjacent side edges of two adjacent sub-pixel openings are arranged parallel to each other and spaced apart by a first distance D1; and closest points between adjacent sub-pixel lenses are spaced apart by a second distance D2 less than the first distance D1.

In some exemplary embodiments of the present disclosure, the orthographic projections of the plurality of sub-pixel lenses on the base substrate have a same diameter.

In some exemplary embodiments of the present disclosure, an orthographic projection of a center of the sub-pixel lens on the base substrate coincides with an orthographic projection of a center of the corresponding sub-pixel opening on the base substrate.

In some exemplary embodiments of the present disclosure, each pixel unit includes two first color sub-pixels having the same color, a second color sub-pixel having a different color from the first color sub-pixels, and a third color sub-pixel having a different color from the first color sub-pixels and the second color sub-pixel: first sub-pixel lenses corresponding to the first color sub-pixels has first centers: a second sub-pixel lens corresponding to the second color sub-pixel has a second center: a third sub-pixel lens corresponding to the third color sub-pixel has a third center; and a shape formed by sequentially connecting the first centers, the second center and the third center is a square.

In some exemplary embodiments of the present disclosure, the sub-pixels of the plurality of pixel units are spaced apart in a first direction and a second direction intersecting with the first direction; and the first distance D1 includes: a first direction distance D11 between adjacent side edges of sub-pixels adjacent in the first direction: a second direction distance D12 between adjacent side edges of sub-pixels adjacent in the second direction; and the second direction distance D12 is greater than or equal to the first direction distance D11.

In some exemplary embodiments of the present disclosure, the first color sub-pixel includes a first sub-pixel opening, the second color sub-pixel includes a second sub-pixel opening, and the third color sub-pixel includes a third sub-pixel opening; and an area S1 of the first sub-pixel opening, an area S2 of the second sub-pixel opening, and an area S3 of the third sub-pixel opening meet a relationship of S1≥S2≥S3.

In some exemplary embodiments of the present disclosure, an orthographic projection of the first sub-pixel opening on the base substrate is inscribed in an orthographic projection of the first sub-pixel lens on the base substrate.

In some exemplary embodiments of the present disclosure, an orthographic projection of the second sub-pixel opening on the base substrate is inscribed in an orthographic projection of the second sub-pixel lens on the base substrate.

In some exemplary embodiments of the present disclosure, an orthographic projection of the third sub-pixel opening on the base substrate is inscribed in an orthographic projection of the third sub-pixel lens on the base substrate.

In some exemplary embodiments of the present disclosure, the display substrate further includes: an anode layer provided between the pixel defining layer and the base substrate, the orthographic projection of the sub-pixel opening on the base substrate is located within an orthographic projection of the anode layer on the base substrate, the anode layer includes: a first anode corresponding to the first color sub-pixel: a second anode corresponding to the second color sub-pixel: a third anode corresponding to the third color sub-pixel; and an orthographic projection of the first anode on the base substrate, an orthographic projection of the second anode on the base substrate and an orthographic projection of the third anode on the base substrate do not overlap.

In some exemplary embodiments of the present disclosure, orthographic projections of sub-pixel openings of the first color sub-pixels having the same color in each pixel unit on the base substrate are located within the orthographic projection of a same first anode on the base substrate.

In some exemplary embodiments of the present disclosure, the first anode includes a first sub-anode corresponding to one of the first color sub-pixels, and a second sub-anode corresponding to the other of the first color sub-pixels; and an orthographic projection of the first sub-anode on the base substrate and an orthographic projection of the second sub-anode on the base substrate do not overlap.

In some exemplary embodiments of the present disclosure, the display substrate further includes: a control circuit provided between the anode layer and the base substrate, the control circuit includes a first control sub-circuit configured to control an on/off state of the first sub-anode and a second control sub-circuit configured to control an on/off state of the second sub-anode.

In some exemplary embodiments of the present disclosure, the control circuit is configured to: control, by the first control sub-circuit, the first sub-anode to turn on, and in response to an electric current of the first sub-anode being greater than or equal to half of a maximum current, control, by the second control sub-circuit, the second sub-anode to turn on.

In some exemplary embodiments of the present disclosure, the control circuit is configured to: in a first time period, control, by the first control sub-circuit, the first sub-anode to turn on, and simultaneously control, by the second control sub-circuit, the second sub-anode not to turn on; and in a second time period, control, by the first control sub-circuit, the first sub-anode not to turn on, and simultaneously control, by the second control sub-circuit, the second sub-anode to turn on.

In some exemplary embodiments of the present disclosure, the first color sub-pixel includes a blue sub-pixel, the second color sub-pixel includes a green sub-pixel, and the third color sub-pixel includes a red sub-pixel; and a ratio of S2/S3 is in a range of 1 to 2.5.

In some exemplary embodiments of the present disclosure, the orthographic projection of the sub-pixel opening on the base substrate is a square or a rectangle.

In some exemplary embodiments of the present disclosure, the orthographic projection of the sub-pixel opening on the base substrate includes a first side edge close to an adjacent sub-pixel opening: the orthographic projection of the sub-pixel lens corresponding to the sub-pixel opening on the base substrate has a first arc edge close to an adjacent sub-pixel lens, and the first side edge and the first arc edge are located on a same side of the orthographic projection; and a maximum distance D3 between the first side edge and the first arc edge is less than the second distance D2.

In another aspect of the present disclosure, a method of manufacturing a display substrate is provided, the display substrate having a display region, and the method including: providing a base substrate: constituting a plurality of pixel units on a side of the base substrate, the plurality of pixel units are arranged in an array in the display region, each pixel unit includes a plurality of sub-pixels, and the sub-pixels include sub-pixel openings defined by a pixel defining layer provided on the base substrate: constituting a plurality of sub-pixel lenses on a side of the pixel defining layer away from the base substrate, the sub-pixel lenses have corresponding sub-pixel openings in the pixel defining layer on a side close to the base substrate, the plurality of sub-pixels of each pixel unit include at least two sub-pixels having a same color: an orthographic projection of the sub-pixel opening on the base substrate is a parallelogram, an orthographic projection of the sub-pixel lens on the base substrate is a circle, and the orthographic projection of the sub-pixel opening on the base substrate is located within the orthographic projection of the corresponding sub-pixel lens on the base substrate; and adjacent side edges of two adjacent sub-pixel openings are arranged parallel to each other and spaced apart by a first distance D1, and closest points between adjacent sub-pixel lenses are spaced apart by a second distance D2 less than the first distance D1.

In yet another aspect of the present disclosure, a display device is provided, including the display substrate as described above.

### BRIEF DESCRIPTION OF THE DRAWINGS

The features and advantages of the present disclosure will be more apparent through the detailed descriptions of exemplary embodiments of the present disclosure with reference to the accompanying drawings. In the accompanying drawings:

FIG. 1 shows a schematic diagram of a planar structure of a display substrate according to exemplary embodiments of the present disclosure:

FIG. 2A shows a partial enlarged view of a pixel unit of a display substrate according to an exemplary embodiment of the present disclosure:

FIG. 2B shows a schematic diagram of a partial cross-sectional structure of the display substrate taken along line B-B in FIG. 2A, according to an exemplary embodiment of the present disclosure:

FIG. 2C shows a schematic diagram of a partial cross-sectional structure of the display substrate taken along line B-B in FIG. 2A, according to another exemplary embodiment of the present disclosure;

FIG. 3 shows a partial enlarged view of a pixel unit of a display substrate according to another exemplary embodiment of the present disclosure:

FIG. 4 shows a partial enlarged view of a pixel unit of a display substrate according to still another exemplary embodiment of the present disclosure:

FIG. 5 shows a schematic diagram of a size structure of a pixel unit of a display substrate according to an exemplary embodiment of the present disclosure:

FIG. 6 shows a schematic diagram of a size structure of a pixel unit of a display substrate according to another exemplary embodiment of the present disclosure:

FIG. 7 shows a schematic structural diagram of a display device according to an exemplary embodiment of the present disclosure.

It should be noted that for the sake of clarity, in the accompanying drawings used to describe the embodiments of the present disclosure, sizes of layers, structures or regions may be enlarged or reduced, that is, those accompanying drawings are not drawn according to actual scale.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out any inventive effort fall within the scope of protection of the present disclosure.

It should be noted that in the accompanying drawings, for clarity and/or description purposes, a size and relative size of an element may be enlarged. Accordingly, the size and relative size of each element are not necessarily limited to those shown in the drawings. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It should be noted that although the terms “first”, “second”, etc. may be used here to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, etc. may be used here to describe a relationship between an element or feature and another element or feature as shown in the drawing. It should be understood that the spatial relationship terms are intended to cover other different orientations of a device in use or operation in addition to the orientation described in the drawing. For example, if a device in the drawing is turned upside down, an element or feature described as “below” or “under” another element or feature will be oriented “above” or “on” the another element or feature.

It should be noted that the expression “the same layer” herein refers to a layer structure that is formed by firstly forming, using a same film forming process, a film layer used to form a specific pattern, and then patterning, using an one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or referred to as a size in a normal direction of the display device.

Herein, the directional expressions “first direction” and “second direction” are used to describe different directions along a pixel region, e.g., a longitudinal direction and a transverse direction of the pixel region, or a row direction and a column direction in which the sub-pixels are arranged. It should be understood that such expressions are just exemplary descriptions and not limitations to the present disclosure.

Some exemplary embodiments of the present disclosure provide a display substrate having a display region. The display substrate includes but is not limited to: a base substrate: a plurality of pixel units arranged in an array in the display region, where each pixel unit includes a plurality of sub-pixels, and each sub-pixel includes a sub-pixel opening defined by a pixel defining layer provided on the base substrate: a plurality of sub-pixel lenses arranged in an array on a side of the pixel defining layer away from the base substrate, where each sub-pixel lens has a corresponding sub-pixel opening in the pixel defining layer on a side close to the base substrate. The plurality of sub-pixels of each pixel unit include at least two sub-pixels having a same color. An orthographic projection of the sub-pixel opening on the base substrate is a parallelogram, and an orthographic projection of the sub-pixel lens on the base substrate is a circle. The orthographic projection of each sub-pixel opening on the base substrate is located within the orthographic projection of a corresponding sub-pixel lens on the base substrate. Adjacent side edges of two adjacent sub-pixel openings are arranged parallel to each other and spaced apart by a first distance D1. Closest points between adjacent sub-pixel lenses are spaced apart by a second distance D2, which is less than the first distance D1.

In the display device according to the embodiments of the present disclosure, by providing a plurality of sub-pixel lenses on the side of the pixel defining layer away from the base substrate, a light extraction efficiency of the sub-pixels may be improved. By providing at least two sub-pixels having the same color in the pixel unit and arranging adjacent side edges of two adjacent sub-pixel openings to be parallel to each other, a maximum opening rate in each pixel unit may be achieved under an extreme pixel opening manufacturing process. By providing the orthographic projection of the sub-pixel lens on the base substrate as a circle, providing at least two sub-pixels having the same color in the pixel unit, and providing the second distance D2 between the closest points between adjacent sub-pixel lenses to be greater than the first distance D1 between adjacent side edges of adjacent sub-pixel openings, a maximum opening rate in each pixel unit may be ensured under the process of extreme distance between adjacent sub-pixel lenses. In this way, the light extraction efficiency of the display substrate may be improved, and the demand for high pixel density may be satisfied.

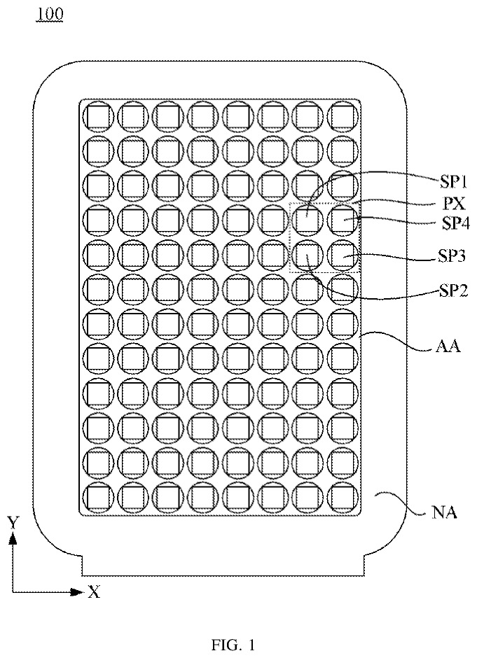

FIG. 1 shows a schematic diagram of a planar structure of a display substrate according to exemplary embodiments of the present disclosure.

As shown in FIG. 1, a display substrate 100 includes a display region AA and a non-display region NA.

The display region AA may be a region in which pixel units PX for displaying images are provided. Each pixel unit PX will be described later. The non-display region NA may be a region in which no pixel unit PX is provided, that is, a region in which no image is displayed. The non-display region NA corresponds to a bezel in a final display device, and a width of the bezel may be determined according to a width of the non-display region NA.

The display region AA may have various shapes. For example, the display region AA may be provided in various shapes such as a closed polygon including straight sides (e.g., a rectangle), a circle, an ellipse, etc. that includes a curved side, and a semicircle, a semi-ellipse, etc. that includes a straight side and a curved side. In the embodiments of the present disclosure, the display region AA is provided as a region having a quadrangular shape including straight sides. It should be understood that this is just an exemplary embodiment rather than a limitation to the present disclosure.

The non-display region NA may be arranged on at least one side of the display region AA. In the embodiments of the present disclosure, the non-display region NA may surround a periphery of the display region AA. In the embodiments of the present disclosure, the non-display region NA may include a transverse portion extending in a first direction X and a longitudinal portion extending in a second direction Y.

The pixel unit PX is arranged in the display region AA. The pixel unit PX is a minimum unit for displaying an image, and a plurality of pixel units may be provided. For example, the pixel unit PX may include light emitting device(s) emitting white light and/or color light. The pixel units PX are arranged in an array in the display region, for example, arranged sequentially in the first direction X and the second direction Y. A plurality of pixel units PX may be arranged in a matrix form along rows extending in the first direction X and columns extending in the second direction Y. However, the embodiments of the present disclosure do not specifically limit an arrangement form of the pixel units PX, and the pixel units PX may be arranged in various forms. For example, the pixel units PX may be arranged such that a direction inclined with respect to the first direction X and the second direction Y is a column direction, and a direction intersecting with the column direction is a row direction.

That is, a plurality of pixel units PX are arranged in an array in the first direction X and the second direction Y, so as to form a plurality of rows of pixel units and a plurality of columns of pixel units.

A pixel unit PX may include a plurality of sub-pixels. For example, a pixel unit PX may include four sub-pixels, namely a first sub-pixel SP1, a second sub-pixel SP2, a third sub-pixel SP3, and a fourth sub-pixel SP4. For example, the sub-pixels may be provided as having the same color or different colors. For example, the first sub-pixel SP1 and the second sub-pixel SP2 may be sub-pixels having the same color, such as blue sub-pixels, the third sub-pixel SP3 may be a red sub-pixel, and the fourth sub-pixel SP4 may be a green sub-pixel. In some embodiments of the present disclosure, the four sub-pixels may be arranged in the first direction X and the second direction Y respectively, so that the plurality of sub-pixels in a pixel unit PX are arranged in an array.

It should be noted that in the embodiments of the present disclosure, the number of sub-pixels included in a pixel unit is not particularly restricted, and is not limited to the above-mentioned four, but may be, for example, more than four. In this embodiment, the pixel units in FIG. 1 are just illustrative. In the accompanying drawings used to describe the embodiments of the present disclosure, sizes of pixel units and sub-pixels may be enlarged or reduced, that is, those accompanying drawings are not drawn according to actual scale.

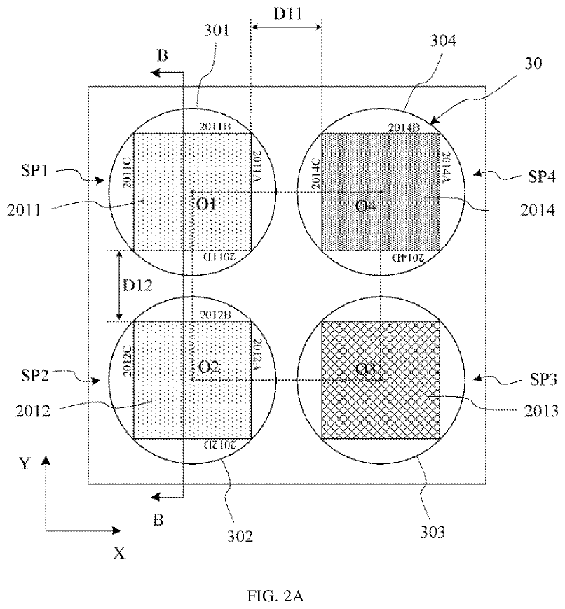

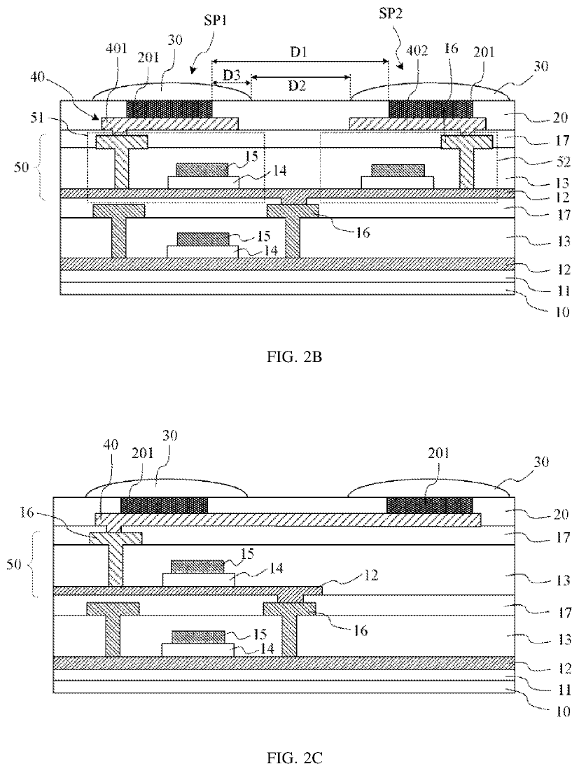

FIG. 2A shows a partial enlarged view of a pixel unit of the display substrate according to an exemplary embodiment of the present disclosure. FIG. 2B shows a schematic diagram of a partial cross-sectional structure of the display substrate taken along line B-B in FIG. 2A, according to an exemplary embodiment of the present disclosure. FIG. 2C shows a schematic diagram of a partial cross-sectional structure of the display substrate taken along line B-B in FIG. 2A, according to another exemplary embodiment of the present disclosure.

As shown in FIG. 1, FIG. 2A, and FIG. 2B, the display substrate 100 includes a base substrate 10. A plurality of film layers, such as a buffer layer, a semiconductor layer, a gate layer, a source/drain layer, a plurality of insulation layers, a passivation layer, etc., are provided on a side of the base substrate 10.

Exemplarily, as shown in FIG. 2B, a buffer layer 11 is provided on a side of the base substrate 10, a semiconductor layer 12 is provided on a side of the buffer layer 11 away from the base substrate, and an interlayer dielectric layer 13, a gate insulation layer 14 and a gate layer 15 are provided on a side of the semiconductor layer 12 away from the base substrate. For example, the interlayer dielectric layer 13 is provided on a side of the semiconductor layer 12, the gate insulation layer 14 and the gate layer 15 away from the base substrate 10. A source/drain layer 16 is provided on a side of the interlayer dielectric layer 13 away from the base substrate 10, and the source/drain layer 16 is electrically connected to the semiconductor layer 12 through a via hole. A passivation layer 17 is provided on a side of the source/drain layer 16 away from the base substrate 10. A second semiconductor layer 12 is provided on a side of the passivation layer 17 away from the base substrate 10. A second interlayer dielectric layer 13, a second gate insulation layer 14 and a second gate layer 15 are provided on a side of the second semiconductor layer 12 away from the base substrate 10. For example, the second interlayer dielectric layer 13 is provided on a side of the second semiconductor layer 12, the second gate insulation layer 14 and the second gate layer 15 away from the base substrate 10. A second source/drain layer 16 is provided on a side of the second interlayer dielectric layer 13 away from the base substrate 10, and the second source/drain layer 16 is electrically connected to the second semiconductor layer 12 through a via hole. A second passivation layer 17 is provided on a side of the second source/drain layer 16 away from the base substrate 10.

As shown in FIG. 1, a plurality of pixel units PX are arranged in an array in the display region AA of the display substrate 100 of the embodiments of the present disclosure. Each pixel unit PX includes a plurality of sub-pixels, and the plurality of sub-pixels of each pixel unit PX include at least two sub-pixels having a same color. For example, each pixel unit includes four sub-pixels, and the four sub-pixels including sub-pixels having three colors, that is, the four sub-pixels include two sub-pixels having the same color.

In some optional embodiments, each pixel unit of the display substrate includes two or more, such as four or more, sub-pixels having the same color. In other optional embodiments, each pixel unit of the display substrate includes sub-pixels having multiple colors, and sub-pixels of each color may include a plurality of sub-pixels.

As shown in FIG. 2A and FIG. 2B, each sub-pixel includes a sub-pixel opening 201 defined by a pixel defining layer 20 provided on the base substrate. For example, the pixel defining layer 20 is provided on a side of the passivation layer 17 away from the base substrate 10.

A plurality of sub-pixel lenses 30 are arranged in an array on a side of the pixel defining layer 20 away from the base substrate 10. Each sub-pixel lens 30 has a corresponding sub-pixel opening 201 on a side close to the base substrate 10. The sub-pixel openings 201 are provided with luminescent materials of different colors, so that different sub-pixels generate different colors of light. The sub-pixel lens 30 is provided on a side of the pixel defining layer 20 away from the base substrate 10, and the sub-pixel lens 30 covers a side of the sub-pixel opening 201 away from the base substrate 10, so as to concentrate the light generated by the luminescent material in the sub-pixel opening, thereby improving a light extraction efficiency of each sub-pixel and improving an overall light extraction efficiency and display effect of an entire display substrate.

An orthographic projection of the sub-pixel opening 201 on the base substrate is a parallelogram. For example, the orthographic projection of the sub-pixel opening 201 on the base substrate 10 is a square and/or a rectangle, that is, the orthographic projection of the sub-pixel opening in each pixel unit on the base substrate may be a square or a rectangle. The sub-pixel openings in each pixel unit may include squares and rectangles. For example, the sub-pixel openings are all provided as squares, or all provided as rectangles, or provided as a mixture of squares and rectangles.

As shown in FIG. 2B, a side of a cross-section of the sub-pixel lens 30 away from the base substrate has an arc-shaped surface, which may concentrate the light emitted by the luminescent material to increase a sub-pixel light extraction brightness and improve a brightness of the display substrate. An orthographic projection of the sub-pixel lens 30 on the base substrate 10 is a circle. As shown in FIG. 2A, when viewed from a direction perpendicular to a surface of the display substrate, the sub-pixel lens 30 is a circle. An orthographic projection of each sub-pixel opening 201 on the base substrate 10 is located within an orthographic projection of a corresponding sub-pixel lens 30 on the base substrate.

By arranging the orthographic projection of the sub-pixel opening on the base substrate within the orthographic projection of the sub-pixel lens on the base substrate, it is ensured that each sub-pixel lens may have a good concentration effect on the light emitted by the luminescent material in the sub-pixel opening, thereby improving the light extraction efficiency and brightness.

In some embodiments of the present disclosure, the plurality of pixel units are arranged in an array in the first direction X and the second direction Y, and the sub-pixels in each pixel unit are also arranged in an array in the first direction X and the second direction Y, with adjacent side edges of adjacent sub-pixel openings parallel to each other.

In some embodiments of the present disclosure, the pixel unit PX includes sub-pixels having three colors, that is, each pixel unit contains three colors. For example, a first-color sub-pixel is a blue sub-pixel, and there may be two or more first-color sub-pixels. A second-color sub-pixel is a red sub-pixel, and a third-color sub-pixel is a green sub-pixel. In other embodiments, the pixel unit may include sub-pixels having more colors.

FIG. 2A schematically shows a schematic diagram of a planar structure of a pixel unit. The sub-pixels having three colors in the pixel unit include four sub-pixels, namely the first sub-pixel SP1, the second sub-pixel SP2, the third sub-pixel SP3, and the fourth sub-pixel SP4. The first sub-pixel SP1 includes a first sub-pixel opening 2011 and a first sub-pixel lens 301, the second sub-pixel SP2 includes a second sub-pixel opening 2012 and a second sub-pixel lens 302, the third sub-pixel SP3 includes a third sub-pixel opening 2013 and a third sub-pixel lens 303, and the fourth sub-pixel SP4 includes a fourth sub-pixel opening 2014 and a fourth sub-pixel lens 304. The first sub-pixel SP1 and the second sub-pixel SP2 are provided as displaying the same color, that is, the first sub-pixel opening 2011 and the second sub-pixel opening 2012 are filled with the same luminescent material. For example, both the first sub-pixel SP1 and the second sub-pixel SP2 are used to emit blue light, that is, both the first sub-pixel SP1 and the second sub-pixel SP2 are blue sub-pixels. The third sub-pixel SP3 may be used to emit, for example, red light, that is, the third sub-pixel SP3 is a red sub-pixel. The fourth sub-pixel SP4 may be used to emit, for example, green light, that is, the fourth sub-pixel SP4 is a green sub-pixel.

When manufacturing an OLED display substrate, a minimum distance between adjacent sub-pixel openings (i.e., a width of the pixel defining layer between adjacent sub-pixel openings) is related to a manufacturing process. When an extreme size of the manufacturing process is reached, the minimum distance between adjacent sub-pixel openings is the extreme size of the manufacturing process. Due to the demand for higher pixel density, the number of pixel units per unit area increases, and the number of sub-pixel openings per unit area also increases, which inevitably results in a gradual decrease in a pixel opening rate. In order to achieve a maximum opening rate in a case of the extreme size of the manufacturing process, the adjacent side edges of adjacent sub-pixel openings may be arranged parallel to each other, that is, a size of the pixel defining layer between adjacent sub-pixel openings is the same as the extreme size of the manufacturing process, so that the maximum opening rate may be achieved in the case of the extreme size of the manufacturing process.

As shown in FIG. 2A, adjacent side edges of two adjacent sub-pixel openings 201 are arranged parallel to each other. For example, in the first direction X, the first sub-pixel SP1 and the fourth sub-pixel SP4 are adjacent, the first sub-pixel opening 2011 of the first sub-pixel SP1 has a side edge close to the fourth sub-pixel, the fourth sub-pixel opening 2014 of the fourth sub-pixel SP4 has a side edge close to the first sub-pixel, and the two adjacent side edges are spaced apart by a first distance D1.

For another example, in the second direction Y, the first sub-pixel SP1 and the second sub-pixel SP2 are adjacent, the first sub-pixel opening 2011 of the first sub-pixel SP1 has a side edge close to the second sub-pixel SP2, the second sub-pixel opening 2012 of the second sub-pixel SP2 has a side edge close to the first sub-pixel, and the two adjacent side edges are spaced apart by a first distance D1.

In some embodiments of the present disclosure, the orthographic projections of the plurality of sub-pixel lenses on the base substrate 10 have a same diameter, that is, the plurality of sub-pixel lenses 30 are set to a same size. Adjacent sub-pixel lenses 30 are spaced apart by a second distance D2. As the second distance D2 is a minimum spacing for forming the sub-pixel lenses 30, it is possible to form a maximum number of sub-pixel lenses per unit area, so as to improve a concentration effect of the sub-pixels.

In the embodiments of the present disclosure, the second distance D2 is less than the first distance D1, that is, the sub-pixel opening does not completely overlap with the sub-pixel lens. In the related art, a method of completely overlapping the sub-pixel opening with the sub-pixel lens is used to improve the light extraction efficiency of the sub-pixel. However, when the sub-pixel opening completely overlaps with the sub-pixel lens, the sub-pixel opening is a circle, and a pixel opening rate of the circle sub-pixel opening is lower compared with that of the sub-pixel opening having paralleled side edges, which may not meet a design of high-density pixel arrangement. By setting the second distance D2 to be less than the first distance D1, the pixel opening rate may be improved, and the design of high-density pixel arrangement may be met.

In some embodiments of the present disclosure, an orthographic projection of a center of each sub-pixel lens on the base substrate coincides with an orthographic projection of a center of a corresponding sub-pixel opening on the base substrate. As shown in FIG. 2A, an orthographic projection of a center of the first sub-pixel lens 301 on the base substrate coincides with an orthographic projection of a center of the first sub-pixel opening 2011 on the base substrate 10, which is point O1. An orthographic projection of a center of the second sub-pixel lens 302 on the base substrate coincides with an orthographic projection of a center of the second sub-pixel opening 2012 on the base substrate 10, which is point O2. An orthographic projection of a center of the third sub-pixel lens 303 on the base substrate coincides with an orthographic projection of a center of the third sub-pixel opening 2013 on the base substrate 10, which is point O3. An orthographic projection of a center of the fourth sub-pixel lens 304 on the base substrate coincides with an orthographic projection of a center of the fourth sub-pixel opening 2014 on the base substrate 10, which is point O4.

According to the embodiments of the present disclosure, with the arrangement that the orthographic projection of the center of each sub-pixel lens on the base substrate coincides with the orthographic projection of the center of the corresponding sub-pixel opening on the base substrate, the sub-pixel lens may have a good concentration effect on the light emitted by the luminescent material filled in the sub-pixel opening, thereby improving a light extraction intensity of each sub-pixel.

In some embodiments of the present disclosure, with the arrangement that the orthographic projection of each sub-pixel opening on the base substrate is located within the orthographic projection of the corresponding sub-pixel lens on the base substrate and the orthographic projections of the plurality of sub-pixel lenses on the base substrate have the same diameter, it is possible to achieve the maximum pixel opening rate of the display substrate while improving the overall light extraction efficiency and light intensity of the display substrate.

In the embodiment shown in FIG. 2A, each pixel unit PX includes the first sub-pixel SP1 and the second sub-pixel SP2 having the same color, the third sub-pixel SP3 having a different color from the first sub-pixel SP1 and the second sub-pixel SP2, and the fourth sub-pixel SP4 having a different color from the first sub-pixel and the third sub-pixel.

During a process of manufacturing sub-pixel lenses, the second distance D2 between adjacent sub-pixel lenses needs to be greater than or equal to an extreme size of the process of manufacturing sub-pixel lenses. If the second distance D2 between adjacent sub-pixel lenses is less than the extreme size of the process of manufacturing sub-pixel lenses, the manufactured sub-pixel lenses may fail to achieve the concentration effect, or even have defects, which may result in a deterioration in a display effect of the display substrate or even product defects. In order to avoid occurrence of the above-mentioned problems, in some embodiments of the present disclosure, each sub-pixel lens has a center, and a square may be formed by sequentially connecting centers of the sub-pixel lenses corresponding to the above-mentioned four sub-pixels. For example, a square O1O2O3O4 may be formed by sequentially connecting point O1, point O2, point O3, and point O4. A distance between O1 and O2, a distance between O2 and O3, a distance between O3 and O4, and a distance between O4 and O1 are extreme sizes of the process of manufacturing sub-pixel lenses, so that the sub-pixel lenses per unit area may cover the sub-pixel openings to a maximum extent without producing defects or reducing the concentration effect, and the concentration effect on the light generated by the luminescent material in the sub-pixel opening may be improved. Furthermore, in order to maximize the pixel opening rate on the display substrate, each sub-pixel opening is provided as a rectangle or a square, so that the pixel opening rate per unit area may be significantly improved, and the design of high-resolution display substrate may be met.

As shown in FIG. 2A, the sub-pixels include sub-pixels arranged at intervals in the first direction X and sub-pixels arranged at intervals in the second direction Y. The first distance D1 between adjacent side edges of adjacent sub-pixel openings include: a first direction distance D11 between adjacent side edges of sub-pixels adjacent in the first direction X, and a second direction distance D12 between adjacent side edges of sub-pixels adjacent in the second direction Y.

For example, the first sub-pixel opening 2011 of the first sub-pixel SP1 includes four side edges, namely side edge 2011A, side edge 2011B, side edge 2011C, and side edge 2011D. The first sub-pixel SP1 is adjacent to the fourth sub-pixel SP4 in the first direction X. The fourth sub-pixel opening 2014 of the fourth sub-pixel SP4 includes four side edges, namely side edge 2014A, side edge 2014B, side edge 2014C, and side edge 2014D. The side edge 2011A of the first sub-pixel opening 2011 is adjacent to the side edge 2014C of the fourth sub-pixel opening 2014, and a distance between the side edge 2011A and the side edge 2014C is the first direction distance D11.

For another example, the first sub-pixel SP1 is adjacent to the second sub-pixel SP2 in the second direction Y. The second sub-pixel opening 2012 of the second sub-pixel SP2 includes four side edges, namely side edge 2012A, side edge 2012B, side edge 2012C, and side edge 2012D. The side edge 2011D of the first sub-pixel opening 2011 is adjacent to the side edge 2012B of the second sub-pixel opening 2012, and a distance between the side edge 2011D and the side edge 2012B is the second direction distance D12.

In the embodiment shown in FIG. 2A, the first direction distance D11 is equal to the second direction distance D12. By providing the first direction distance D11 to be equal to the second direction distance D12, each pixel unit in the display substrate may have the maximum opening rate, so as to meet the demand for high resolution.

As shown in FIG. 2A, the orthographic projection of each sub-pixel opening on the base substrate has a first side edge close to an adjacent sub-pixel opening, and the orthographic projection of the sub-pixel lens corresponding to the sub-pixel opening on the base substrate has a first arc edge close to an adjacent sub-pixel lens. The first side edge and the first arc edge are located on a same side of the orthographic projection. For example, the first sub-pixel opening 2011 has the first side edge 2011A close to the fourth sub-pixel opening 2014. The orthographic projection of the sub-pixel lens 301 corresponding to the first sub-pixel opening 2011 on the base substrate has a first arc edge 301A close to the adjacent sub-pixel lens 304, and there is a maximum distance D3 between the first side edge 2011A and the first arc edge 301A. By providing the maximum distance D3 to be less than the second distance D2, a region of each sub-pixel lens not covering the pixel opening is minimized, so that the pixel density of the display substrate may be maximized while ensuring the brightness improvement and maximum pixel opening rate, thereby meeting the design demands for high-resolution display substrate.

As shown in FIG. 2A, the first sub-pixel opening 2011 has an area S11, the second sub-pixel opening 2012 has an area S12, the third sub-pixel opening 2013 has an area S13, and the fourth sub-pixel opening 2014 has an area S14. S11=S12=S13=S14, that is, all sub-pixel openings in a pixel unit have the same area.

The first sub-pixel and the second sub-pixel are blue sub-pixels having the same color, the third sub-pixel is a red sub-pixel, and the fourth sub-pixel is a green sub-pixel. The orthographic projection of the first sub-pixel opening on the base substrate is inscribed in the orthographic projection of the first sub-pixel lens on the base substrate, the orthographic projection of the second sub-pixel opening on the base substrate is inscribed in the orthographic projection of the second sub-pixel lens on the base substrate, the orthographic projection of the third sub-pixel opening on the base substrate is inscribed in the orthographic projection of the third sub-pixel lens on the base substrate, and the orthographic projection of the fourth sub-pixel opening on the base substrate is inscribed in the orthographic projection of the fourth sub-pixel lens on the base substrate.

According to the embodiments of the present disclosure, with the arrangement that the orthographic projection of the sub-pixel opening in a pixel unit on the base substrate is inscribed in the orthographic projection of the corresponding sub-pixel lens on the base substrate, a non-overlapping region between the sub-pixel lens and the sub-pixel opening is reduced, and the pixel opening rate in the pixel unit is increased.

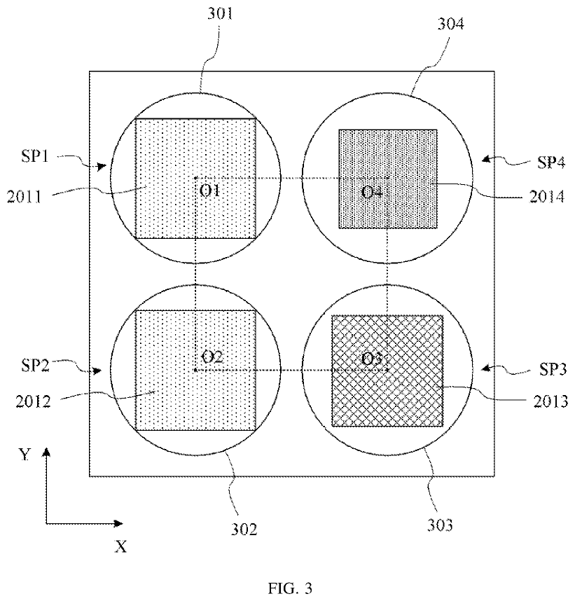

FIG. 3 shows a partial enlarged view of a pixel unit of the display substrate according to another exemplary embodiment of the present disclosure.

In another embodiment of the present disclosure, as shown in FIG. 3, the first sub-pixel SP1 and the second sub-pixel SP2 are blue sub-pixels having the same color, the third sub-pixel SP3 is a red sub-pixel, and the fourth sub-pixel SP4 is a green sub-pixel.

The orthographic projection of the first sub-pixel opening 2011 on the base substrate is inscribed in the orthographic projection of the first sub-pixel lens 301 on the base substrate. The orthographic projection of the second sub-pixel opening 2012 on the base substrate is inscribed in the orthographic projection of the second sub-pixel lens 302 on the base substrate. The orthographic projection of the third sub-pixel opening 2013 on the base substrate is located within the orthographic projection of the third sub-pixel lens 303 on the base substrate, but the orthographic projection of the third sub-pixel opening 2013 on the base substrate is not inscribed in the orthographic projection of the third sub-pixel lens 303 on the base substrate. The orthographic projection of the fourth sub-pixel opening 2014 on the base substrate is located within the orthographic projection of the fourth sub-pixel lens 304 on the base substrate, but the orthographic projection of the fourth sub-pixel opening 2014 on the base substrate is not inscribed in the orthographic projection of the fourth sub-pixel lens 304 on the base substrate. In this embodiment, the area S11 of the first sub-pixel opening 2011 is equal to the area S12 of the second sub-pixel opening 2012, S11 and S12 are greater than the area S13 of the third sub-pixel opening 2013, and S13 is greater than the area S14 of the fourth sub-pixel opening 2014, that is, S11=S12>S13>S14. In other words, in a pixel unit, the blue sub-pixel has a largest area, the red sub-pixel has an area less than the area of the blue sub-pixel, and the green sub-pixel has an area less than the area of the red sub-pixel.

In some optional embodiments, in a pixel unit, the blue sub-pixel has a largest area, the red sub-pixel has an area less than the area of the blue sub-pixel, and the green sub-pixel has an area equal to the area of the red sub-pixel.

In other embodiments, in order to meet a white balance setting of the display substrate, the size of the sub-pixel openings in each pixel unit may be appropriately adjusted while keeping the second distance D2 between sub-pixel lenses unchanged. For example, the area of the sub-pixel opening of the blue sub-pixel remains unchanged, the area of the sub-pixel opening of the red sub-pixel is reduced, and the area of the sub-pixel opening of the green sub-pixel is reduced.

Exemplarily, the area S11 of the first sub-pixel opening is equal to the area S12 of the second sub-pixel opening, the area S13 of the third sub-pixel opening and the area S14 of the fourth sub-pixel opening are less than the area S11 and the area S12, and a ratio of the area S13 to the area S14 is in a range of 1 to 2.5, so that the display substrate may have a good white balance effect.

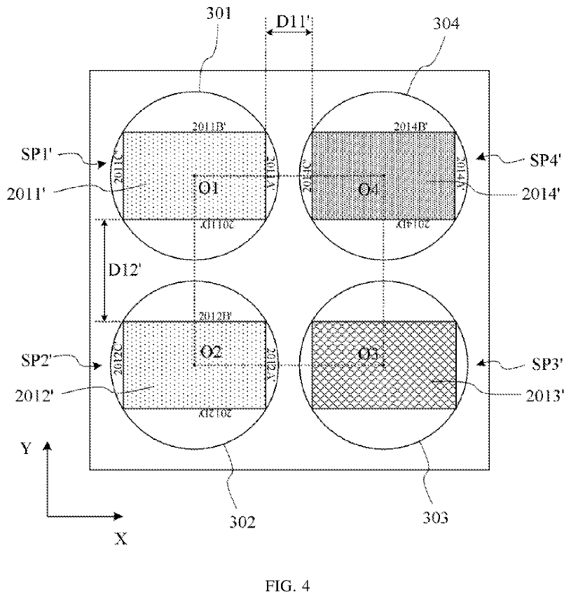

FIG. 4 shows a partial enlarged view of a pixel unit of the display substrate according to still another exemplary embodiment of the present disclosure.

In other embodiments of the present disclosure, as shown in FIG. 4, the orthographic projections of four sub-pixel openings in a pixel unit on the base substrate are rectangles. In the embodiment, a first sub-pixel SP1′ and a second sub-pixel SP2′ are blue sub-pixels having the same color, a third sub-pixel SP3′ is a red sub-pixel, and a fourth sub-pixel SP4′ is a green sub-pixel. The four sub-pixels in a pixel unit have the same area.

The sub-pixels include sub-pixels arranged at intervals in the first direction X and sub-pixels arranged at intervals in the second direction Y. The first distance D1 between adjacent side edges of adjacent sub-pixel openings includes: a first direction distance D11′ between adjacent side edges of sub-pixels adjacent in the first direction X, and a second direction distance D12′ between adjacent side edges of sub-pixels adjacent in the second direction Y.

As shown in the drawing, a first sub-pixel opening 2011′ of the first sub-pixel SP1′ includes four side edges, namely side edge 2011A′, side edge 2011B′, side edge 2011C′, and side edge 2011D′. The first sub-pixel SP1′ is adjacent to the fourth sub-pixel SP4′ in the first direction X. A fourth sub-pixel opening 2014′ of the fourth sub-pixel SP4′ includes four side edges, namely side edge 2014A′, side edge 2014B′, side edge 2014C′, and side edge 2014D′. The side edge 2011A′ of the first sub-pixel opening 2011′ is adjacent to the side edge 2014C′ of the fourth sub-pixel opening 2014′, and a distance between the side edge 2011A′ and the side edge 2014C′ is the first direction distance D11′. The first sub-pixel SP1′ is adjacent to the second sub-pixel SP2′ in the second direction Y. A second sub-pixel opening 2012′ of the second sub-pixel SP2′ includes four side edges, namely side edge 2012A′, side edge 2012B′, side edge 2012C′, and side edge 2012D′. The side edge 2011D′ of the first sub-pixel opening 2011′ is adjacent to the side edge 2012B′ of the second sub-pixel opening 2012′, and a distance between the side edge 2011D′ and the side edge 2012B′ is the second direction distance D12′. The second direction distance D12′ is greater than the first direction distance D11′.

According to the embodiments of the present disclosure, by providing the sub-pixel openings in a pixel unit into rectangular structures, it is possible to meet designs of different display effects without significantly reducing the opening rate of the pixel unit of the display substrate.

In some embodiments of the present disclosure, as shown in FIG. 2B, the display substrate 100 further includes an anode layer 40 provided between the pixel defining layer 20 and the base substrate 10. Specifically, the anode layer 40 is provided between the pixel defining layer 20 and the passivation layer 17. The orthographic projection of the sub-pixel opening on the base substrate is located within an orthographic projection of the anode layer 40 on the base substrate.

The anode layer 40 includes anodes corresponding to sub-pixels of each color, for example, a first anode corresponding to the first color sub-pixel, a second anode corresponding to the second color sub-pixel, and a third anode corresponding to the third color sub-pixel. An orthographic projection of the first anode on the base substrate, an orthographic projection of the second anode on the base substrate, and an orthographic projection of the third anode on the base substrate do not overlap. That is, in each pixel unit, the sub-pixel of each color has a corresponding anode electrode used to provide an electrical signal for the sub-pixel of different colors.

In some exemplary embodiments of the present disclosure, the orthographic projections of the first sub-pixel openings of the first color sub-pixels having the same color in each pixel unit on the base substrate are located within an orthographic projection of a same first anode on the base substrate. As shown in FIG. 2C, the first color sub-pixel includes a first sub-pixel SP1 and a second sub-pixel SP2. The first sub-pixel SP1 and the second sub-pixel SP2 may be provided as blue sub-pixels. The orthographic projection of the first sub-pixel opening of the first sub-pixel SP1 on the base substrate and the orthographic projection of the second sub-pixel opening of the second sub-pixel SP2 on the base substrate are located within an orthographic projection of a same first anode on the base substrate, that is, the first sub-pixel SP1 and the second sub-pixel SP2 share the same anode.

In other exemplary embodiments of the present disclosure, as shown in FIG. 2B, the first anode includes a first sub-anode 401 corresponding to one of the first color sub-pixels, and a second sub-anode 402 corresponding to the other of the first color sub-pixels. An orthographic projection of the first sub-anode 401 on the base substrate and an orthographic projection of the second sub-anode 402 on the base substrate do not overlap.

As shown in FIG. 2B, the first sub-pixel SP1 and the second sub-pixel SP2 are both blue sub-pixels. The first sub-anode corresponding to the first sub-pixel SP1 and the second sub-anode corresponding to the second sub-pixel SP2 are different sub-anodes. The first sub-pixel SP1 and the second sub-pixel SP2 are provided with electrical signals through different sub-anodes, so that the first sub-pixel and the second sub-pixel having the same color in the same pixel unit may be controlled separately. Specifically, the first sub-pixel SP1 is provided with an electrical signal through the first sub-anode 401, and the second sub-pixel SP2 is provided with an electrical signal through the second sub-anode 402.

As shown in FIG. 2B, the display substrate 100 further includes a control circuit 50. The control circuit 50 is provided between the anode layer 40 and the base substrate 10. For example, the control circuit 50 is formed by designing a plurality of film layers such as the semiconductor layer 12, the interlayer dielectric layer 13, the gate insulation layer 14, the gate layer 15, the source/drain layer 16, and the passivation layer 17. By inputting different electrical signals into the control circuit 50, an on/off state of the anode corresponding to the sub-pixel may be controlled.

As shown in FIG. 2B, the control circuit 50 includes a first control sub-circuit 51 that controls an on/off state of the first sub-anode 401, and a second control sub-circuit 52 that controls an on/off state of the second sub-anode 402. When the first sub-anode 401 is turned on, the luminescent material filled in the first sub-pixel opening emits light. When the second sub-anode 402 is turned on, the luminescent material filled in the second sub-pixel opening emits light. By controlling a current flowing through the first sub-anode 401 and/or the second sub-anode 402 in the circuit, a luminous intensity may be controlled.

During a light emission process of sub-pixels in the display substrate, especially when organic luminescent materials are filled in pixel openings, a longtime light emission may lead to a decrease in a lifetime of the luminescent materials, and a high brightness may also lead to a decrease in the lifetime of the luminescent materials, thereby shortening a service life of the display substrate. In order to avoid the above-mentioned problems, in some embodiments of the present disclosure, the control circuit is configured to: control, by the first control sub-circuit, the first sub-anode to turn on, and control, by the second control sub-circuit, the second sub-anode to turn on when an electric current of the first sub-anode is greater than or equal to half of a maximum current.

Exemplarily, different sub-pixels having the same color in a pixel unit are controlled separately by the first control sub-circuit 51 and the second control sub-circuit 52. For example, when the electric current of the first sub-anode 401 is greater than or equal to half of the maximum current, it indicates that the light emission brightness corresponding to the first sub-pixel SP1 increases, then the second sub-anode 402 may be turned on under a control of the second control sub-circuit 52, so that the second sub-pixel SP2 may compensate for the light emission brightness of the first sub-pixel SP1. When the light emission brightness in the pixel unit is low, one of the two sub-pixels having the same color may be turned off, thereby improving the service life of the sub-pixel.

In other embodiments of the present disclosure, the control circuit 50 is configured to: in a first time period, control, by the first control sub-circuit 511, the first sub-anode 401 to turn on, and simultaneously control, by the second control sub-circuit 52, the second sub-anode 402 not to turn on. In a second time period, control, by the first control sub-circuit 51, the first sub-anode 401 not to turn on, and simultaneously control, by the second control sub-circuit 52, the second sub-anode 402 to turn on.

That is, in different time periods, different sub-pixels having the same color in the same pixel unit are controlled to light up in turn. For example, when the sub-pixels having the same color are both in a low brightness mode, in the first time period, one sub-pixel is controlled to light up and the other is controlled to turn off, and in the second time period, the other sub-pixel is controlled to light up and the one sub-pixel is controlled to turn off, so that the sub-pixels having the same color light up in turn to improve the service life of the pixel.

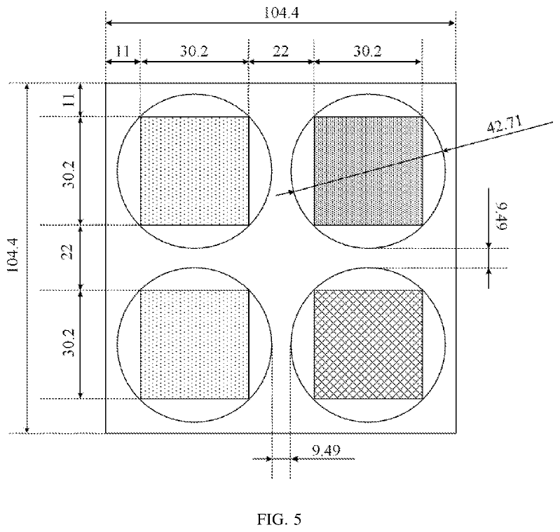

FIG. 5 shows a schematic diagram of a size structure of a pixel unit of the display substrate according to an exemplary embodiment of the present disclosure.

A size structure of a pixel unit is shown in FIG. 5. In this embodiment, the pixel unit is a square with a side length of 104.4 μm. Each pixel unit includes four sub-pixels, namely two blue sub-pixels, one red sub-pixel, and one green sub-pixel. The sub-pixel opening of each sub-pixel is provided as a square with a same size. That is, the orthographic projection of the sub-pixel opening on the base substrate is a square with a side length of 30.2 μm. The first distance D1 between adjacent side edges of adjacent sub-pixel openings is 22 μm. Each sub-pixel opening has a corresponding sub-pixel lens, with a diameter of 42.71 μm. The second distance D2 between the closest points of adjacent sub-pixel lenses is 9.49 μm. According to such pixel opening design, it is possible to achieve the maximum pixel opening rate.

The pixel opening rate is a ratio of an opening area of each pixel unit to a total area of the pixel unit. For example, in this embodiment, the opening area of each pixel unit is 30.2×30.2×4=3648.16 μm². The total area of each pixel unit is 104.4×104.4=10899.36 μm². Accordingly, the pixel opening rate is 33.5%.

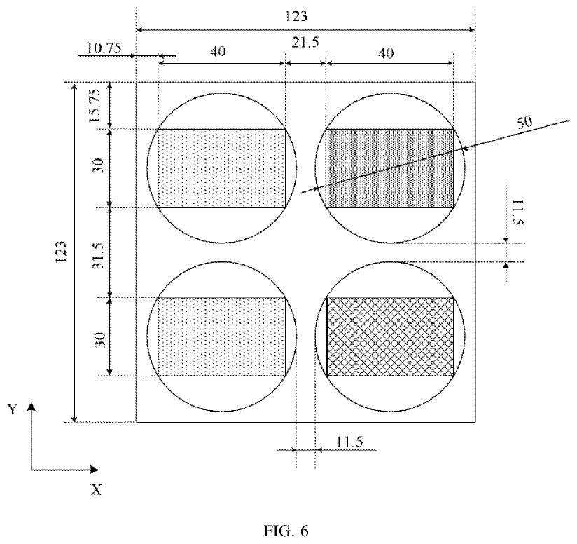

FIG. 6 shows a schematic diagram of a size structure of a pixel unit of the display substrate according to another exemplary embodiment of the present disclosure.

A size structure of another pixel unit is shown in FIG. 6. In this embodiment, the pixel unit is a square with a side length of 123 μm. Each pixel unit includes four sub-pixels, namely two blue sub-pixels, one red sub-pixel, and one green sub-pixel. The sub-pixel opening of each sub-pixel is provided as a rectangle with a same size. The orthographic projection of the sub-pixel opening on the base substrate is a rectangle, with a length of 40 μm and a width of 30 μm. The first direction distance D11 between adjacent side edges of the sub-pixel openings adjacent in the first direction X is 21.5 μm, and the second direction distance D12 between adjacent side edges of sub-pixel openings adjacent in the second direction Y is 31.5 μm. That is, the second direction distance D12 is greater than the first direction distance D11. Each sub-pixel opening has a corresponding sub-pixel lens, with a diameter of 50 μm. The second distance D2 between the closest points of adjacent sub-pixel lenses is 11.5 μm. According to such pixel opening design, the pixel opening rate is 31.7%, so that a large opening rate may be achieved with a good white balance.

The embodiments of the present disclosure further provide a method of manufacturing a display substrate having a display region. The manufacturing method includes operation S101 to operation S103.

In operation S101, a base substrate is provided.

In operation S102, a plurality of pixel units are formed on a side of the base substrate. The plurality of pixel units are arranged in an array in the display region. Each pixel unit includes a plurality of sub-pixels, and each sub-pixel includes a sub-pixel opening defined by a pixel defining layer provided on the base substrate.

In operation S103, a plurality of sub-pixel lenses are formed on a side of the pixel defining layer away from the base substrate. Each sub-pixel lens has a corresponding sub-pixel opening in the pixel defining layer on a side close to the base substrate. The plurality of sub-pixels in each pixel unit include at least two sub-pixels having the same color. An orthographic projection of the sub-pixel opening on the base substrate is a parallelogram, and an orthographic projection of the sub-pixel lens on the base substrate is a circle. The orthographic projection of each sub-pixel opening on the base substrate is located within the orthographic projection of a corresponding sub-pixel lens on the base substrate. Adjacent side edges of two adjacent sub-pixel openings are arranged parallel to each other and spaced apart by a first distance D1. Closest points between adjacent sub-pixel lenses are spaced apart by a second distance D2, which is less than the first distance D1.

According to the embodiments of the present disclosure, by providing a plurality of sub-pixel lenses on a side of the pixel defining layer away from the base substrate, the light extraction efficiency of the sub-pixels may be improved. By providing at least two sub-pixels having the same color in the pixel unit and arranging adjacent side edges of two adjacent sub-pixel openings to be parallel to each other, the maximum opening rate in each pixel unit may be achieved under the manufacturing process of extreme pixel openings. By providing the orthographic projection of the sub-pixel lens on the base substrate as a circle, providing at least two sub-pixels having the same color in the pixel unit, and providing the second distance D2 between the closest points between adjacent sub-pixel lenses to be greater than the first distance D1 between adjacent side edges of adjacent sub-pixel openings, the maximum opening rate in each pixel unit may be ensured under the process of extreme distance between adjacent sub-pixel lenses. In this way, the light extraction efficiency of the display substrate may be improved, and the demand for high pixel density may be satisfied.

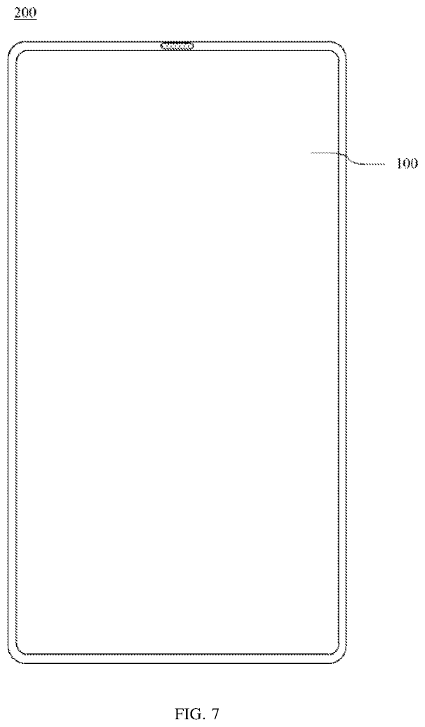

FIG. 7 shows a schematic structural diagram of a display device according to an exemplary embodiment of the present disclosure.

In some embodiments of the present disclosure, as shown in FIG. 7, the embodiments of the present disclosure further provide a display device 200, which may include the above-mentioned display substrate 100.

Beneficial effects that the display device in the aforementioned embodiments of the present disclosure may achieve are the same as the beneficial effects that the above-mentioned display substrate may achieve, which will not be repeated here.

The above-mentioned display device may be any device that displays a moving image (e.g., a video) or a fixed image (e.g., a still image) and that displays a text or an image. More specifically, it is expected that the embodiments may be implemented in or associated with various electronic devices. The various electronic devices may include (but not be limited to) a mobile phone, a wireless device, a personal data assistant (PDA), a handheld or portable computer, a GPS receiver/navigator, a camera, a MP4 video player, a video camera, a game console, a watch, a clock, a calculator, a television monitor, a flat panel display, a computer monitor, a vehicle display (e.g., odometer display), a navigator, a cockpit controller and/or display, a display for camera view (e.g., display of rear view camera in vehicle), an electronic photo, an electronic billboard or sign, a projector, an architectural structure, a packaging and aesthetic structure (e.g., display for image of jewelry), etc.

Herein, the terms “substantially”, “about”, “approximately” “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used here includes a stated value and means that a specific value determined by those ordinary skilled in the art is within an acceptable range of deviation. For example, “about” may mean being within one or more standard deviations, or within +30%, +20%, +10% or +5% of the stated value.

Although some embodiments of the general technical concept of the present disclosure have been illustrated and explained, those ordinary skilled in the art may understand that changes may be made to those embodiments without departing from the principle and spirit of the general technical concept. The scope of the present disclosure is defined by the claims and their equivalents.

1. A display substrate having a display region, the display substrate comprising:
a base substrate;
a plurality of pixel units arranged in an array in the display region, wherein each pixel unit comprises a plurality of sub-pixels, and the sub-pixels comprise sub-pixel openings defined by a pixel defining layer provided on the base substrate;
a plurality of sub-pixel lenses arranged in an array on a side of the pixel defining layer away from the base substrate, wherein the sub-pixel lenses have corresponding sub-pixel openings in the pixel defining layer on a side close to the base substrate,
wherein the plurality of sub-pixels of each pixel unit comprise at least two sub-pixels having a same color;
an orthographic projection of the sub-pixel opening on the base substrate is a parallelogram, an orthographic projection of the sub-pixel lens on the base substrate is a circle, and the orthographic projection of the sub-pixel opening on the base substrate is located within the orthographic projection of the corresponding sub-pixel lens on the base substrate;
adjacent side edges of two adjacent sub-pixel openings are arranged parallel to each other and spaced apart by a first distance D1; and
closest points between adjacent sub-pixel lenses are spaced apart by a second distance D2 less than the first distance D1.

2. The display substrate according to claim 1, wherein the orthographic projections of the plurality of sub-pixel lenses on the base substrate have a same diameter.

3. The display substrate according to claim 1, wherein an orthographic projection of a center of the sub-pixel lens on the base substrate coincides with an orthographic projection of a center of the corresponding sub-pixel opening on the base substrate.

4. The display substrate according to claim 1, wherein each pixel unit comprises two first color sub-pixels having the same color, a second color sub-pixel having a different color from the first color sub-pixels, and a third color sub-pixel having a different color from the first color sub-pixels and the second color sub-pixel;
first sub-pixel lenses corresponding to the first color sub-pixels has first centers;
a second sub-pixel lens corresponding to the second color sub-pixel has a second center;
a third sub-pixel lens corresponding to the third color sub-pixel has a third center; and
a shape formed by sequentially connecting the first centers, the second center and the third center is a square.

5. The display substrate according to claim 4, wherein the sub-pixels of the plurality of pixel units are spaced apart in a first direction and a second direction intersecting with the first direction; and
the first distance D1 comprises:
a first direction distance D11 between adjacent side edges of sub-pixels adjacent in the first direction;
a second direction distance D12 between adjacent side edges of sub-pixels adjacent in the second direction; and
the second direction distance D12 is greater than or equal to the first direction distance D11.

6. The display substrate according to claim 4, wherein the first color sub-pixel comprises a first sub-pixel opening, the second color sub-pixel comprises a second sub-pixel opening, and the third color sub-pixel comprises a third sub-pixel opening; and
an area S1 of the first sub-pixel opening, an area S2 of the second sub-pixel opening, and an area S3 of the third sub-pixel opening meet a relationship of S1>S2>S3.

7. The display substrate according to claim 6, wherein an orthographic projection of the first sub-pixel opening on the base substrate is inscribed in an orthographic projection of the first sub-pixel lens on the base substrate.

8. The display substrate according to claim 7, wherein an orthographic projection of the second sub-pixel opening on the base substrate is inscribed in an orthographic projection of the second sub-pixel lens on the base substrate.

9. The display substrate according to claim 8, wherein an orthographic projection of the third sub-pixel opening on the base substrate is inscribed in an orthographic projection of the third sub-pixel lens on the base substrate.

10. The display substrate according to claim 4, wherein the display substrate further comprises:
an anode layer provided between the pixel defining layer and the base substrate, wherein the orthographic projection of the sub-pixel opening on the base substrate is located within an orthographic projection of the anode layer on the base substrate,
the anode layer comprises:
a first anode corresponding to the first color sub-pixel;
a second anode corresponding to the second color sub-pixel;
a third anode corresponding to the third color sub-pixel; and
an orthographic projection of the first anode on the base substrate, an orthographic projection of the second anode on the base substrate and an orthographic projection of the third anode on the base substrate do not overlap.

11. The display substrate according to claim 10, wherein orthographic projections of sub-pixel openings of the first color sub-pixels having the same color in each pixel unit on the base substrate are located within the orthographic projection of a same first anode on the base substrate.

12. The display substrate according to claim 10, wherein the first anode comprises a first sub-anode corresponding to one of the first color sub-pixels, and a second sub-anode corresponding to the other of the first color sub-pixels; and
an orthographic projection of the first sub-anode on the base substrate and an orthographic projection of the second sub-anode on the base substrate do not overlap.

13. The display substrate according to claim 12, wherein the display substrate further comprises:
a control circuit provided between the anode layer and the base substrate, wherein the control circuit comprises a first control sub-circuit configured to control an on/off state of the first sub-anode and a second control sub-circuit configured to control an on/off state of the second sub-anode.

14. The display substrate according to claim 13, wherein the control circuit is configured to:
control, by the first control sub-circuit, the first sub-anode to turn on, and in response to an electric current of the first sub-anode being greater than or equal to half of a maximum current, control, by the second control sub-circuit, the second sub-anode to turn on.

15. The display substrate according to claim 13, wherein the control circuit is configured to: in a first time period, control, by the first control sub-circuit, the first sub-anode to turn on, and simultaneously control, by the second control sub-circuit, the second sub-anode not to turn on; and
in a second time period, control, by the first control sub-circuit, the first sub-anode not to turn on, and simultaneously control, by the second control sub-circuit, the second sub-anode to turn on.

16. The display substrate according to claim 6, wherein the first color sub-pixel comprises a blue sub-pixel, the second color sub-pixel comprises a green sub-pixel, and the third color sub-pixel comprises a red sub-pixel; and
a ratio of S2/S3 is in a range of 1 to 2.5.

17. The display substrate according to claim 1, wherein the orthographic projection of the sub-pixel opening on the base substrate is a square or a rectangle.

18. The display substrate according to claim 1, wherein the orthographic projection of the sub-pixel opening on the base substrate comprises a first side edge close to an adjacent sub-pixel opening;
the orthographic projection of the sub-pixel lens corresponding to the sub-pixel opening on the base substrate has a first arc edge close to an adjacent sub-pixel lens, and the first side edge and the first arc edge are located on a same side of the orthographic projection; and
a maximum distance D3 between the first side edge and the first arc edge is less than the second distance D2.

19. A method of manufacturing a display substrate, the display substrate having a display region, and the method comprising:
providing a base substrate;
constituting a plurality of pixel units on a side of the base substrate, wherein the plurality of pixel units are arranged in an array in the display region, each pixel unit comprises a plurality of sub-pixels, and the sub-pixels comprise sub-pixel openings defined by a pixel defining layer provided on the base substrate;
constituting a plurality of sub-pixel lenses on a side of the pixel defining layer away from the base substrate, wherein the sub-pixel lenses have corresponding sub-pixel openings in the pixel defining layer on a side close to the base substrate,
wherein the plurality of sub-pixels of each pixel unit comprise at least two sub-pixels having a same color;
an orthographic projection of the sub-pixel opening on the base substrate is a parallelogram, an orthographic projection of the sub-pixel lens on the base substrate is a circle, and the orthographic projection of the sub-pixel opening on the base substrate is located within the orthographic projection of the corresponding sub-pixel lens on the base substrate; and
adjacent side edges of two adjacent sub-pixel openings are arranged parallel to each other and spaced apart by a first distance D1, and closest points between adjacent sub-pixel lenses are spaced apart by a second distance D2 less than the first distance D1.

20. A display device, comprising the display substrate according to claim 1.
